(19) United States
(12) Patent Application Publication
(10) Pub. No.: US 2015/0293191 A1
(43) Pub. Date: Oct. 15, 2015

(54) METHOD FOR OPTIMIZING A MAGNETIC RESONANCE SEQUENCE

(71) Applicant: Siemens Aktiengesellschaft, Muenchen (DE)

(72) Inventors: Dominik Paul, Bubenreuth (DE); Joerg Roland, Hemhofen (DE)

(73) Assignee: Siemens Aktiengesellschaft, Muenchen (DE)

(21) Appl. No.: 14/686,000

(22) Filed: Apr. 14, 2015

(30) Foreign Application Priority Data
Apr. 14, 2014 (DE) 102014207099.6

(51) Int. Cl. G01R 33/38; G01R 33/54

(52) U.S. Cl. CPC G01R 33/38; G01R 33/543

(57) ABSTRACT

In a method and device for optimizing a magnetic resonance sequence for operating a magnetic resonance apparatus, in order provide effective optimization of the magnetic resonance sequence, particularly with regard to optimizing the slew rates of gradient switching sequences of the magnetic resonance sequence, the magnetic resonance sequence has multiple gradient switching sequences, each having a slew rate, and optimization at least of one gradient switching sequence of the multiple gradient switching sequences is implemented by an iterative adjustment in the slew rate of the at least one gradient switching sequence.

### BACKGROUND OF THE INVENTION

1. Field of the Invention

The invention concerns a method for optimizing a magnetic resonance sequence of a magnetic resonance apparatus, a method for operating a magnetic resonance apparatus, a sequence optimizing device, a magnetic resonance apparatus and a storage medium with programming instructions that cause a computer to execute such a method.

2. Description of the Prior Art

In a magnetic resonance apparatus, also known as a magnetic resonance tomography system, the body of the subject to be examined, particularly that of a patient, is typically exposed to a relatively strong magnetic field of, for example, 1.5 or 3 or 7 Tesla, with the use of a basic field magnet. In addition, gradient switching sequences are applied by a gradient coil unit. With a radio-frequency antenna unit, using suitable antenna devices, radio-frequency pulses, particularly excitation pulses, are radiated that cause nuclear spins of particular atoms excited into resonance by these radio-frequency pulses to be tilted through a defined flip angle relative to the magnetic field lines of the basic magnetic field. Upon relaxation of the nuclear spin, radio-frequency signals known as magnetic resonance signals are emitted and are received by suitable radio-frequency antennae, and then further processed. From the raw data thereby acquired, the desired image data can ultimately be reconstructed.

For a particular scan, a specific magnetic resonance sequence, also known as a pulse sequence is to be employed, which is composed of a sequence of radio-frequency pulses, in particular excitation pulses and refocusing pulses, as well as gradient switching sequences to be activated suitably coordinated therewith on various gradient axes along different spatial directions. Temporally adapted thereto, readout windows are set that specify the time frames within which the induced magnetic resonance signals are detected.

The gradient switching sequences specified by means of the magnetic resonance sequence can lead to the magnetic resonance device having a high level of loudness during the acquisition of the magnetic resonance images.

### SUMMARY OF THE INVENTION

An object of the invention is to provide effective optimization of a magnetic resonance sequence, particularly with regard to optimizing the slew rates of gradient switching sequences of the magnetic resonance sequence.

In the method according to the invention, a magnetic resonance sequence of a magnetic resonance apparatus is optimized, the magnetic resonance sequence including multiple gradient switching sequences, each having a slew rate, and wherein optimization of at least one gradient switching sequence of multiple gradient switching sequences is done by an iterative adjustment of the slew rate of the at least one gradient switching sequence is carried out.

In particular, a complete, or transmission-ready but in the method according to the invention, still optimizable, magnetic resonance sequence is used as a starting sequence. This magnetic resonance sequence typically has a number, that is, one or more, of radio-frequency pulses, for example, at least one excitation and/or refocusing pulse and a number of gradient switching sequences temporally coordinated therewith.

Each gradient switching sequence has a slew rate. The slew rate is typically also referred to as the edge steepness of the gradient switching sequence. The slew rate is the first derivative of the gradient edge amplitude dG/dt of the gradient switching sequences. The gradient switching sequences of the non-optimized magnetic resonance sequence have non-optimized slew rates, whereas the gradient switching sequences of the optimized magnetic resonance sequence have optimized slew rates. As noted, each of the multiple gradient switching sequences has a slew rate. One of the multiple gradient switching sequences can also have more than one slew rate. For example, for one of the multiple of gradient switching sequences, different slew rates can be present for the rise or fall of the gradient amplitude of the gradient switching sequence at the start and end of the gradient switching sequence.

A gradient switching sequence can have multiple gradient pulses. Thus, a plurality of gradient pulses can be grouped together into a gradient switching sequence. For example, a fat saturation element of the magnetic resonance sequence can include multiple gradient pulses that can then be grouped together to a fat saturation gradient switching sequence. The slew rate of the gradient switching sequence can be the slew rate of the gradient pulse of the gradient switching sequence with the highest slew rate, or a mean slew rate over all the gradient pulses of the gradient switching sequence.

In the optimization of the at least one gradient switching sequence, the slew rate of the at least one gradient switching sequence is adjusted so that, after completion of the iterative adjustment of the slew rate, the optimized gradient switching sequence has a lower slew rate than the non-optimized gradient switching sequence. An objective of the optimization of the at least one gradient switching sequence can thus be the presence of the lowest possible slew rate of the at least one optimized gradient switching sequence. Any desired number of the multiple gradient switching sequences, in particular all of the gradient switching sequences, can be optimized.

The iterative adjustment of the slew rate of the at least one gradient switching sequence means that the slew rate of the at least one gradient switching sequence is adjusted in steps. Thus, the slew rate of the at least one gradient switching sequence can be adjusted in one or more iterations. The result of an adjustment of the slew rate of the at least one gradient switching sequence in one iteration is used, in particular, as the starting value of the adjustment of the slew rate of the at least one gradient switching sequence in the following iteration. In each iteration, the slew rate of the at least one gradient switching sequence can be increased or reduced. The increase and/or reduction in the slew rate can take place in percentage steps from an original slew rate of the gradient switching sequence. The iterations of the adjustment of the slew rate of the at least one gradient switching sequence can be carried out according to an iteration algorithm. The iterative adjustment of slew rates of multiple gradient switching sequences can be done separately for each individual gradient switching sequence of the multiple gradient switching sequences.

The slew rate of the at least one gradient switching sequence is adjusted iteratively until a termination criterion is reached. As a possible termination criterion, for example, a discrete grid can be defined for steps of the adjustment in the slew rate, and the iterative adjustment in the slew rate can be discontinued as soon as the step size of the change in the slew rate is smaller than the separation of two raster points of the discrete raster. It is also possible for the iterative adjustment in the slew rate to be discontinued as soon as the slew rate has reached or undershot a particular value.

Thus, the optimization of the at least one gradient switching sequence of the magnetic resonance sequence is advantageously directed toward acoustic noise optimization, particularly an acoustic noise reduction of the magnetic resonance sequence. During a magnetic resonance sequence, the magnetic gradient coils, with which the gradient switching sequences are emitted, are frequently and rapidly switched. Since the time pre-selections within a magnetic resonance sequence are mostly very strict and also the overall duration of a magnetic resonance sequence, which determines the overall duration of a magnetic resonance examination, must be kept as short as possible, gradient amplitudes of about 40 mT/m and slew rates of up to 200 mT/m/ms must sometimes be achieved. In particular, such a high edge steepness contributes to the known noise manifestations during switching of the gradient switching sequences. In addition, steep flanks of the gradient switching sequences lead to a higher energy usage and also place greater demands on the gradient coils and other hardware. The rapidly changing gradient fields lead to distortions and oscillations in the gradient switching sequences and to transmission of these energies to the housing of the magnetic resonance device. Due to the resulting heating of the gradient coils and the other components, a high degree of helium boil-off from a cryogen vessel can occur, if the basic magnetic field is generated by superconducting coils.

Using the inventive procedure, by the reduction in the slew rate of the gradient switching sequences, particularly good noise reduction can be achieved. In other words, the optimization of the magnetic resonance sequence preferably takes place with respect to the greatest possible noise reduction in that the gradient shape of the gradient switching sequence is optimized with respect to minimizing the first derivative of the function which defines the gradient shape, the slew rate. Furthermore, in this way, a smaller loading of the gradient system is achieved. Accompanying this are a smaller power consumption, reduced heating of the gradient coils and thus also reduced helium boil-off.

The iterative adjustment of the slew rate of the at least one gradient switching sequence enables a particularly effective and multifaceted optimization of the at least one gradient switching sequence. The number of iterations needed for the iterative adjustment of the slew rate of the at least one gradient switching sequence can be reduced by a procedure according to an embodiment of the method according to the invention, as described below.

In an embodiment, the optimization of the at least one gradient switching sequence includes an operability test of the magnetic resonance sequence that is performed following each iteration of the iterative adjustment. The following iteration of the iterative adjustment is carried out depending on a result of the operability test. With regard to the sequence of a part of the iterative adjustment of the slew rate, therefore, firstly in an iterative step, the slew rate of the gradient switching sequence is adjusted, then the operability test of the magnetic resonance sequence is performed with the gradient switching sequence using the adjusted slew rate and then, depending on the result of the operability test, the slew rate of the gradient switching sequence is adjusted in a subsequent iteration step. The operability test of the magnetic resonance sequence can be a test of whether the magnetic resonance sequence with the gradient switching sequence using the adjusted slew rate is operable on the magnetic resonance device. This means that it is tested as to whether the magnetic resonance sequence can be executed by the magnetic resonance device error-free for the acquisition of magnetic resonance image data. The operability test has a positive result if the magnetic resonance sequence is operable. Otherwise, the operability test has a negative result. An operability test with a negative outcome in one iteration of the adjustment of the slew rate can prevent the adjustment of the slew rate from being terminated after this iteration. Otherwise, the outcome would be a magnetic resonance sequence that is not operable. The operability test can include, for example, a simulation and/or a preparation of the magnetic resonance sequence. This procedure is based on the recognition that the use of excessively low slew rates for the at least one gradient switching sequence can possibly impair the operability of the magnetic resonance sequence. For example, an excessively low slew rate of the gradient switching sequence can have the result that, particularly if the gradient switching sequence has a pre-set duration, an intended gradient moment of the gradient switching sequence can no longer be achieved. An excessively low slew rate of the gradient switching sequence can also have the effect that the two flanks of the gradient switching sequence overlap. The operability test can ensure that the magnetic resonance sequence is still operable without errors following the iterative adjustment of the slew rate of the at least one gradient switching sequence

In another embodiment, upon a positive result of the operability test, the slew rate of the at least one gradient switching sequence is reduced in the following iteration and, upon a negative result of the operability test, the slew rate of the at least one gradient switching sequence is increased in the following iteration. The following iteration is the iteration that immediately follows the iteration of the adjustment of the slew rate underlying the operability test. This procedure is based on the recognition that a slew rate that is too low, as described above leads to magnetic resonance sequence that is no longer operable. Thus, the slew rate of the at least one gradient switching sequence can be reduced for as long as the magnetic resonance sequence is still operable. If it occurs that the magnetic resonance sequence is no longer operable, the slew rate can be increased until the magnetic resonance sequence is operable again. Thus an operable magnetic resonance sequence can be generated with a gradient switching sequence having a particularly low slew rate.

In another embodiment, upon a positive result of the operability test, the slew rate of the at least one gradient switching sequence is reduced in the following iteration by a first step size and, upon a negative result of the operability test, the slew rate of the at least one gradient switching sequence is increased in the following iteration by a second step size. The absolute value of the second step size is smaller than the absolute value of the first step size. In other words, it is proposed that the slew rate of the at least one gradient switching sequence is initially reduced in larger steps, namely the first step size. Upon a negative result of the operability test, fine tuning of the slew rate of the at least one gradient switching sequence can then be done in smaller steps, namely the second step size, until the magnetic resonance sequence is operable again. Thus, a particularly effective iterative adjustment of the slew rate can be carried out and iteration steps can possibly be spared. For example, the calculation outlay for the iterative adjustment of the slew rate can be reduced.

In another embodiment, the absolute value of a step size of the adjustment of the slew rate of the at least one gradient switching sequence is halved with each iteration. This procedure is used in combination with the procedure that, upon a positive result of the operability test, the slew rate of the at least one gradient switching sequence is reduced in the following iteration and, upon a negative result of the operability test, the slew rate of the at least one gradient switching sequence is increased in the following iteration. The slew rate is thus adjusted iteratively, particularly making use of an adapted variant of a binary search algorithm. Thus, the slew rate can be particularly effectively iteratively adjusted and iteration steps can possibly be spared.

In another embodiment, for a first iteration of the iterative adjustment, the slew rate of the at least one gradient switching sequence is set to a minimum slew rate and an operability test of the magnetic resonance sequence is carried out with the at least one gradient switching sequence with the minimum slew rate, and upon a positive result of the operability test, the optimization of the at least one gradient switching sequence is concluded. The minimum slew rate can be, for example, less than one percent of the original slew rate of the gradient switching sequence before the adjustment of the slew rate. The minimum slew rate can also be zero. This procedure is based on the recognition that when executing the magnetic resonance sequence, individual gradient switching sequences of the multiple gradient switching sequences may possibly not be used. These individual gradient switching sequences can then have the minimum slew rate applied to them without problems. The operability of the magnetic resonance sequence is not impaired when the minimum slew rate is set for these individual gradient switching sequences. Thus the iterative adjustment of the slew rate of these individual gradient switching sequences can be terminated immediately following the first iteration step, so that some iteration steps can possibly be spared. If the operability test of the magnetic resonance sequence with the gradient switching sequence with the minimum slew rate has a negative result, then in a second iteration step, the described iterative adjustment of the slew rate from the original value of the slew rate can be begun.

The invention also concerns a method for operating a magnetic resonance apparatus in which, initially in a method according to the invention for optimizing a magnetic resonance sequence, a magnetic resonance sequence is optimized and then the magnetic resonance apparatus is operated using the optimized magnetic resonance sequence. The optimization is preferably done online during the execution, or directly before the execution of the magnetic resonance sequence.

The invention further concerns a sequence optimizing device for optimizing a magnetic resonance sequence of a magnetic resonance device. The sequence optimizing unit has a computer that is configured to implement a method according to the invention. The sequence optimizing device is therefore configured to execute the method for optimizing a magnetic resonance sequence of a magnetic resonance apparatus as described above.

The magnetic resonance sequence has multiple gradient switching sequences, each of which has a slew rate. The sequence optimizing device has an optimizing unit configured to execute an optimization of at least one gradient switching sequence among the multiple gradient switching sequences, such that an iterative adjustment of the slew rate of the at least one gradient switching sequence is implemented.

Embodiments of the sequence optimizing unit according to the invention are configured similarly to the embodiments of the method according to the invention. The sequence optimizing device can have further control components which are necessary and/or advantageous for carrying out a method according to the invention. The sequence optimizing device can also be configured to transmit control signals to a magnetic resonance device and/or to receive and/or process control signals in order to carry out a method according to the invention. Preferably, the sequence optimizing device is part of the control computer of the magnetic resonance apparatus and is preferably connected relatively closely upstream of the radio-frequency antenna unit and/or the gradient coil unit. In a memory of the sequence optimizing device, computer programs and other software can be stored, by which a processor of the sequence optimizing device automatically controls and/or carries out a method sequence of a method according to the invention.

The magnetic resonance apparatus according to the invention has a sequence optimizing device. The magnetic resonance apparatus according to the invention is thus configured to implement a method according to the invention with the sequence optimizing device. The sequence optimizing device can be integrated into the magnetic resonance apparatus. The sequence optimizing device can also be installed separately from the magnetic resonance apparatus. The sequence optimizing device can be connected to the magnetic resonance apparatus.

The data storage medium according to the invention is directly loadable into a memory of a programmable computer of a magnetic resonance apparatus and has program code in order to cause the method according to the invention to be implemented when the code is executed in the computer of the magnetic resonance apparatus. In this way, the method according to the invention can be implemented rapidly, exactly reproducibly and robustly. The computer must have the pre-conditions such as, for example, a suitable working memory store, a suitable graphics card or a suitable logic unit so that the respective method steps can be carried out efficiently. Examples of electronically readable data storage media are a DVD, a magnetic tape or a USB stick, on which electronically readable control information, in particular software (see above) is stored.

The advantages of the method for operating a magnetic resonance apparatus, the sequence optimizing device according to the invention, the magnetic resonance apparatus according to the invention and the storage medium according to the invention substantially correspond to the advantages of the method according to the invention for optimizing a magnetic resonance sequence, as described in detail above. Features, advantages or alternative embodiments mentioned herein are also to be applied equally to the other aspects of the invention, and vice versa. The corresponding functional features of the method are configured as suitable modules, such as hardware modules.

### BRIEF DESCRIPTION OF THE DRAWINGS

FIG. 1 schematically illustrates a magnetic resonance apparatus according to the invention for implementing the method according to the invention.

FIG. 2 is a flowchart of a first embodiment of the method according to the invention.

FIG. 3 is a flowchart of a second embodiment of the method according to the invention.

FIG. 4 illustrates an iterative adjustment of the slew rate of a gradient switching sequence according to a third embodiment of the method according to the invention.

FIG. 5 illustrates an iterative adjustment of the slew rate of a gradient switching sequence according to a fourth embodiment of the method according to the invention.

FIG. 6 illustrates an iterative adjustment of the slew rate of a gradient switching sequence according to a sixth embodiment of the method according to the invention.

### DESCRIPTION OF THE PREFERRED EMBODIMENTS

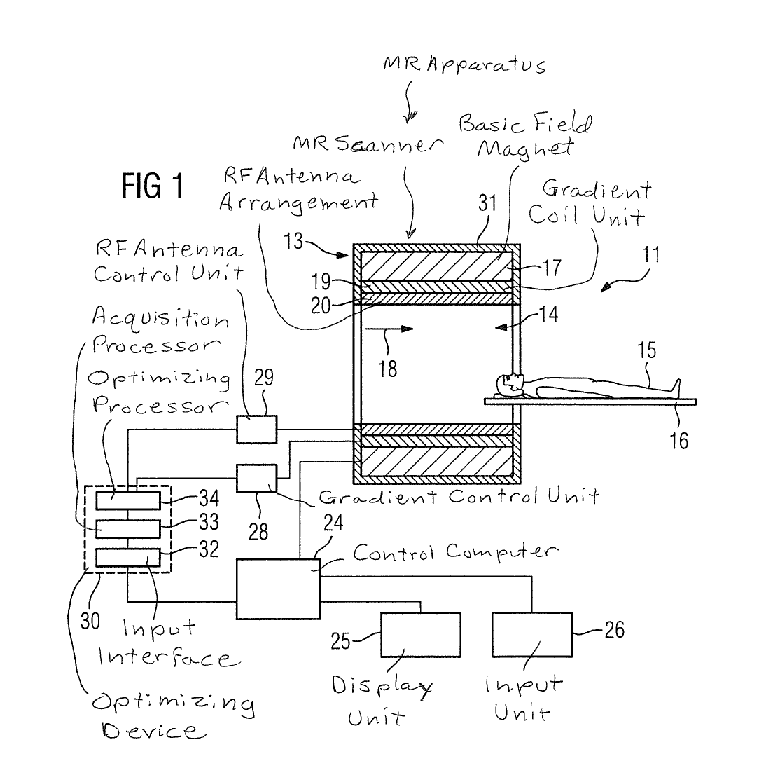

FIG. 1 shows a magnetic resonance apparatus 11 according to the invention for carrying out a method according to the invention, in a schematic illustration. The magnetic resonance apparatus 11 has a scanner 13 with a basic field magnet 17 for generating a strong and basic magnetic field 18. Furthermore, the magnetic resonance apparatus 11 has a cylindrical patient receiving region 14 for accommodating a patient 15, with the patient receiving region 14 being cylindrically enclosed in a peripheral direction by the scanner 13. The patient 15 can be moved by a patient support 16 of the magnetic resonance apparatus 11 into the patient receiving region 14. For this purpose, the patient support 16 has a patient table that is movable within the scanner 13. The scanner 13 is shielded toward the exterior by a housing covering 31 of the magnetic resonance device.

The scanner 13 also has a gradient coil unit 19 for generating magnetic field gradients that are used for spatial encoding during imaging. The gradient coil unit 19 is controlled by a gradient control unit 28. Furthermore, the scanner 13 has a radio-frequency antenna unit 20 that, in the case shown is formed as a body coil built into the magnetic resonance scanner 13, and a radio-frequency antenna control unit 29 for excitation of nuclear spins in the patient 15 and to deflect the spins from alignment with the basic magnetic field 18 generated by the basic field magnet 17. The radio-frequency antenna unit 20 is controlled by the radio-frequency antenna control unit 29 and radiates radio-frequency pulses into an examination space that is substantially formed by the patient receiving region 14.

For controlling the basic field magnet 17, the gradient control unit 28 and the radio-frequency antenna control unit 29, the magnetic resonance apparatus 11 has a control computer 24. The control computer 24 centrally controls the magnetic resonance scanner 13, for the execution of magnetic resonance sequences. Control information such as, for example, imaging parameters and reconstructed magnetic resonance images can be displayed for a user on a display unit 25, for example on at least one monitor of the magnetic resonance apparatus 11. In addition, the magnetic resonance apparatus 11 has an input unit (interface) 26 via which information and/or imaging parameters can be entered by a user during a scanning procedure. The control computer 24 can include the gradient control unit 28 and/or the radio-frequency antenna control unit 29 and/or the display unit 25 and/or the input unit 26.

The magnetic resonance apparatus 11 also has a sequence optimizing unit 30 that includes a processor for optimizing imaging parameters of magnetic resonance sequences. For this purpose, the sequence optimizing unit 30 has an input interface 32, a testing unit 33 and an optimizing unit 34. The magnetic resonance apparatus 11, in particular the sequence optimizing unit 30 thereof, is configured for implementing a method according to the invention.

The magnetic resonance apparatus 11 can naturally include further components that magnetic resonance apparatuses typically have. The general functioning of a magnetic resonance apparatus is known to those skilled in the art, so that a detailed description of the further components is not needed herein.

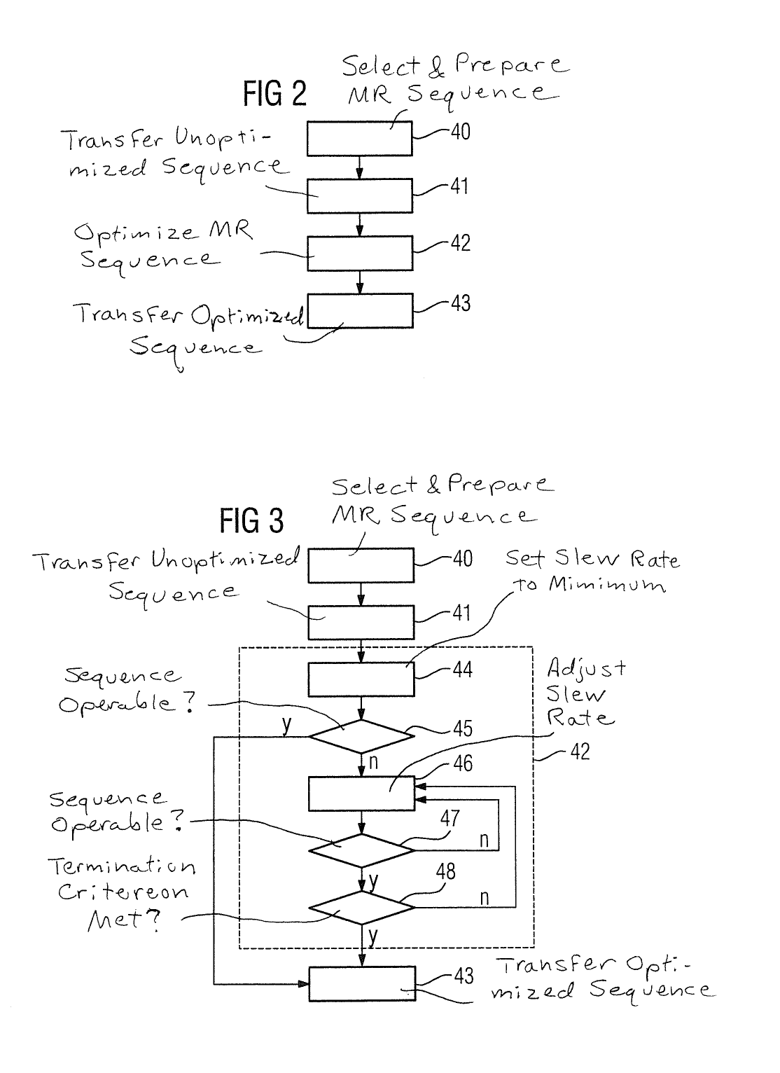

FIG. 2 is a flowchart of a first embodiment of the method according to the invention.

In a first method step 40, initially a selection and preparation of a magnetic resonance sequence of the magnetic resonance apparatus 11 is carried out in the usual manner. This means that typically a user stipulates, via the input unit 26, the type of magnetic resonance sequence and/or seeks a suitable protocol in which a specific magnetic resonance sequence is defined. The protocols contain various imaging parameters for the respective magnetic resonance sequence. These imaging parameters include particular basic data for the desired magnetic resonance sequence, for example, the type of magnetic resonance sequence, that is, whether it is a spin echo sequence, a turbo spin echo sequence, etc. Furthermore, the imaging parameters include slice thicknesses, slice spacings, number of the slices, resolution, repetition times, the echo times in a spin echo sequence, etc. With the use of the input unit 26, the user can modify some of these imaging parameters in order to generate an individual magnetic resonance sequence for a currently desired scan. For this purpose, modifiable imaging parameters are offered to the user, for example, on a graphical user interface of the display unit 25 for modification. The magnetic resonance sequence prepared includes multiple gradient switching sequences, each of which has a slew rate.

In a further method step 41, the transfer of the magnetic resonance sequence that is ready to send, but not yet optimized, takes place. A direct transfer of the magnetic resonance sequence to the gradient control unit 28 and the radio-frequency antenna control unit 29 does not take place. Rather, in the further method step 202, the magnetic resonance sequence is transferred by the computer unit 24, before being transferred to the gradient control unit 28 and the radio-frequency antenna control unit 29, to the sequence optimizing unit 30 for optimizing the magnetic resonance sequence. In this regard, the input interface 32 of the sequence optimizing unit 30 is configured to accept the magnetic resonance sequence which is actually transmission-ready, but is to be optimized.

In a further method step 42, the optimizing unit 34 of the sequence optimizing unit 30 optimizes the magnetic resonance sequence. Herein, the optimizing unit 34 optimizes a gradient switching sequence of the plurality of gradient switching sequences. Herein, the optimizing unit 34 carries out an iterative adjustment of the slew rate of the at least one gradient switching sequence. Herein, the testing unit 33 of the sequence optimizing unit 30 is configured to carry out an operability test of the magnetic resonance sequence with the at least one optimized gradient switching sequence.

In a further method step 43, the optimized magnetic resonance sequence is finally passed by the sequence optimizing unit 30 to the gradient control unit 28 and the radio-frequency antenna control unit 29. The gradient control unit 28 and the radio-frequency antenna control unit 29 generate the relevant control commands from the optimized magnetic resonance sequence and pass these to the radio-frequency antenna unit 20 and the gradient coil unit 19, so that the overall optimized magnetic resonance sequence is played out with, for example, a reduced loudness compared to that before the optimization, in order to record magnetic resonance image data by the magnetic resonance apparatus 11.

FIG. 3 is a flowchart of a second embodiment of a method according to the invention.

The following description is essentially restricted to the differences from the exemplary embodiment in FIG. 2 wherein, with regard to method steps which remain the same, reference can be made to the description of the exemplary embodiment in FIG. 2. In principle, the same method steps are essentially identified with the same reference signs.

The second embodiment of the method according to the invention shown in FIG. 3 includes the method steps 40, 41, 42, 43 of the first embodiment of the method according to the invention as shown in FIG. 2. The second embodiment of the method according to the invention shown in FIG. 3 additionally includes further method steps and sub-steps. Also conceivable is an alternative method sequence to that of FIG. 3 which has only part of the additional method steps and/or sub-steps represented in FIG. 2. Naturally, an alternative method sequence to that of FIG. 3 can also have additional method steps and/or sub-steps.

In the further method step 42 of the optimization of the at least one gradient switching sequence of the magnetic resonance sequence, firstly in a sub-step 44, in a first iteration of the iterative adjustment, the slew rate of the at least one gradient switching sequence is set, by the optimizing unit 34, to a minimum slew rate. Then, in a first checking step 45 by the testing unit 33, an operability test of the magnetic resonance sequence is carried out with the at least one gradient switching sequence with the minimum slew rate. Upon a positive result of the operability test, the optimization of the at least one gradient switching sequence is concluded. The at least one gradient switching sequence that is thus optimized is not used by the magnetic resonance sequence for receiving magnetic resonance image data. Thus, following the optimization of the thus optimized at least one gradient switching sequence, no further gradient switching sequences should need to be optimized and in the further method step 43, the recording of magnetic resonance image data can be continued.

Upon a negative result of the operability test in the first checking step 45, in an iteration step 46, the slew rate of the at least one gradient switching sequence is adjusted iteratively by means of the optimizing unit 34. Then, in an iteration checking step 47 by the testing unit 33, an operability test of the magnetic resonance sequence is carried out. Upon a positive result of the operability test, in a criterion checking step 48, it is checked by the optimizing unit 34 whether a termination criterion for optimizing the at least one gradient switching sequence is met. If this is the case, the magnetic resonance sequence can be used with the gradient switching sequence thus optimized in the iteration step 46, in the further method step 43 for recording magnetic resonance image data.

If the result of the operability test in the iteration checking step 47 was negative or the termination criterion for the optimization of the at least one gradient switching sequence in the criterion checking step 48 is not met, the slew rate of the at least one gradient switching sequence is adjusted again in the iteration step 46. This procedure is carried out iteratively until such time as both the result of the operability test in the iteration checking step 47 is positive and the termination criterion for the optimization of the at least one gradient switching sequence in the criterion checking step 48 is met.

Following each iteration step 46 of the iterative adjustment of the slew rate, the operability test is carried out in the iteration checking step 47, wherein the following iteration of the iterative adjustment of the slew rate is carried out depending on a result of the operability test. Thus, on a positive result of the operability test, the slew rate of the at least one gradient switching sequence is reduced in the following iteration and, on a negative result of the operability test, the slew rate of the at least one gradient switching sequence is advantageously increased in the following iteration. According to a first alternative, upon a positive result of the operability test, the slew rate of the at least one gradient switching sequence can also be reduced in the following iteration by a first step size and, upon a negative result of the operability test, the slew rate of the at least one gradient switching sequence is increased in the following iteration by a second step size, wherein the absolute value of the second step size is advantageously smaller than the absolute value of the first step size. According to a second alternative, the absolute value of a step size of the adjustment of the slew rate of the at least one gradient switching sequence can also be halved with each iteration. Naturally, the step size can also be varied in the iterations according to further criteria that appear meaningful to those skilled in the art.

Naturally, the further method step 42 can be repeated together with its sub-steps for different gradient switching sequences of the plurality of gradient switching sequences.

The method steps of the method according to the invention as shown in FIGS. 2 and 3 are carried out by the magnetic resonance device, in particular by the sequence optimizing unit 30. For this purpose, the magnetic resonance device, in particular the sequence optimizing unit 30, includes required software and/or computer programs which are stored in a storage unit of the magnetic resonance apparatus 11, in particular the sequence optimizing unit 30. The software and/or computer programs include program features that are configured to carry out the method according to the invention if the computer program and/or the software in the magnetic resonance apparatus 11, particularly in the sequence optimizing unit 30, is carried out by of a processor of the magnetic resonance apparatus 11, in particular the sequence optimizing unit 30.

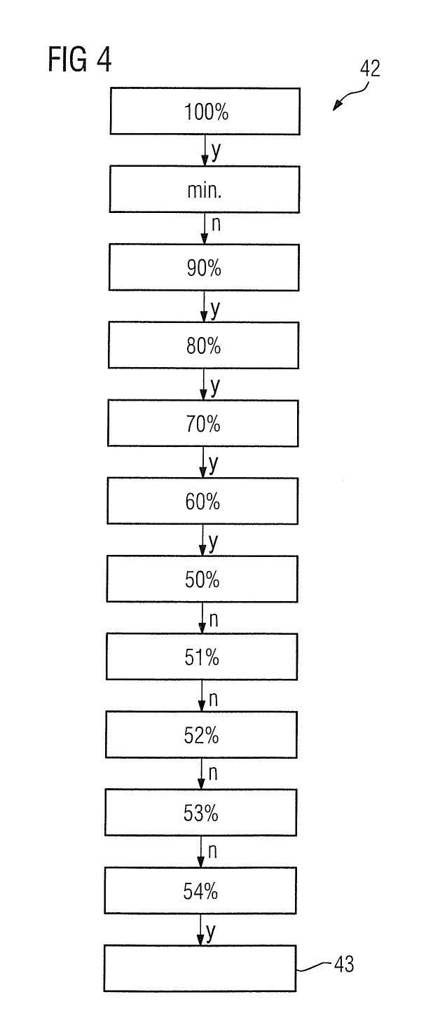

FIG. 4 illustrates an iterative adjustment of a slew rate of a gradient switching sequence according to a third embodiment of a method according to the invention. It should be noted that the iterative adjustment of the slew rate shown in FIGS. 4, 5 and 6 is naturally to be considered as purely exemplary and is intended only for illustration purposes.

FIG. 4 shows the step-wise adjustment of the slew rate in the further method step 42 depending on a starting value which is identified as 100 percent. It is assumed, for example, that the magnetic resonance sequence is still operable when the gradient switching sequence has at least 54 percent of the starting value. Naturally, other percentage values of the starting value are also conceivable for a positive operability test of the magnetic resonance sequence.

In a first step, the slew rate is set to a minimum value, for example, one percent. With this value, the magnetic resonance sequence is not operable, so that the normal iterative adjustment of the slew rate is started.

In the case illustrated in FIG. 4, upon a positive result of the operability test, the slew rate of the gradient switching sequence is reduced in the following iteration by a first step size and, upon a negative result of the operability test, the slew rate of the gradient switching sequence is increased in the following iteration by a second step size, wherein the absolute value of the second step size is smaller than the absolute value of the first step size. The absolute value of the first step size is, for example, ten percent and the absolute value of the second step size is, for example, one percent. The termination criterion is set so that a step size of one percent exists and the magnetic resonance sequence is operable.

Naturally, other possible values for the absolute value of the first step size and/or the second step size are also conceivable. If greater absolute values are selected for the step sizes, the calculation can be accelerated on the basis of a reduced number of iterations, although it becomes less accurate.

Thus, the slew rate of the gradient switching sequence is initially reduced in ten percent steps from 100 percent to 50 percent. At 50 percent of the starting value, it is the case that the magnetic resonance sequence is no longer operable with the optimized gradient switching sequence. Thereafter, the slew rate of the gradient switching sequence is then increased in one percent steps until the magnetic resonance sequence is operable again with the optimized gradient switching sequence with a slew rate of 54 percent of the starting value. Thus, the termination criterion is also met and the optimized gradient switching sequence can be used for recording magnetic resonance image data in the further method step 43.

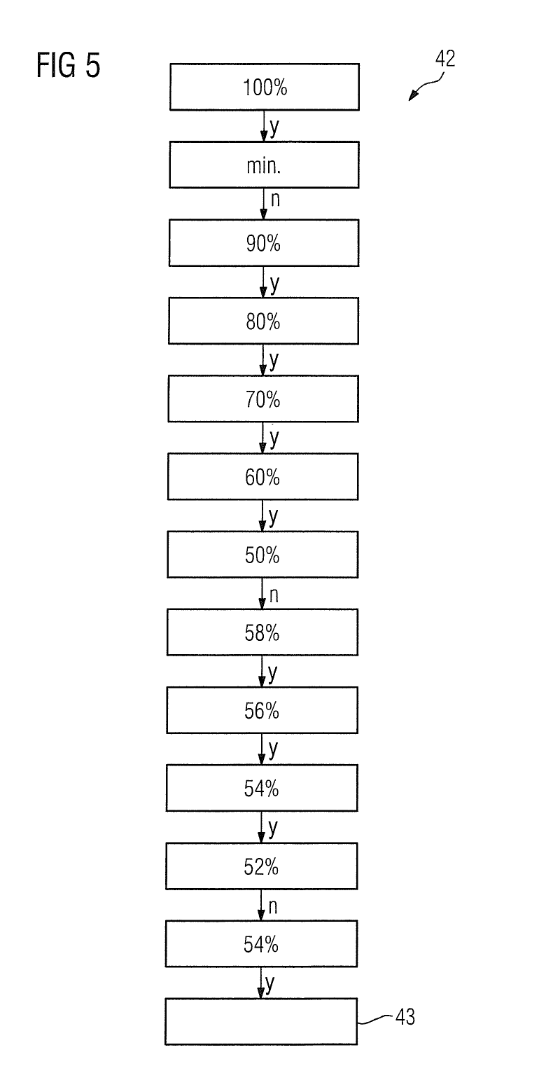

FIG. 5 illustrates an iterative adjustment of a slew rate of a gradient switching sequence according to a fourth embodiment of the method according to the invention.

As in FIG. 4, the step-wise adjustment of the slew rate in the further method step 42 is shown, depending on a starting value which is identified as 100 percent. It is therein assumed again that the magnetic resonance sequence is still operable when the gradient switching sequence has at least 54 percent of the starting value.

In a first step, the slew rate is set to a minimum value, for example, one percent. At this value, the magnetic resonance sequence is not operable, so that the normal iterative adjustment of the slew rate is started.

In the case illustrated in FIG. 5, upon a positive result of the operability test, the slew rate of the gradient switching sequence is reduced in the following iteration by a first step size and, upon a negative result of the operability test, the slew rate of the gradient switching sequence is increased in the following iteration by a second step size, wherein the absolute value of the second step size is smaller than the absolute value of the first step size. The absolute value of the first step size is, for example, ten percent and the absolute value of the second step size is, in contrast to FIG. 4, for example, eight percent.

If following an increase in the slew rate of the gradient switching sequence by the second step size, the operability test gives a positive result, the slew rate of the gradient switching sequence is reduced in the following iterations, in contrast to FIG. 4, by a third step size, wherein the absolute value of the third step size is smaller than the absolute value of the second step size. The third step size is herein, for example, two percent.

It is set as the termination criterion that a step size of eight or two percent exists and the magnetic resonance sequence is operable such that a further reduction of the slew rate of the gradient switching sequence by two percent leads to a negative result of the operability test.

Thus, the slew rate of the gradient switching sequence is initially reduced, as in FIG. 4, in ten percent steps from 100 percent to 50 percent. At 50 percent of the starting value, it is the case that the magnetic resonance sequence is no longer operable with the optimized gradient switching sequence. Thereafter, the slew rate of the gradient switching sequence is then increased by one eight percent step, so that the magnetic resonance sequence is operable again with the gradient switching sequence at a slew rate of 58 percent. The slew rate of the gradient switching sequence is then reduced by two percent steps until the magnetic resonance sequence is no longer operable with the gradient switching sequence at a slew rate of 52 percent. Thereafter, the slew rate of the previous iteration at 54 percent is set for the gradient switching sequence. Thus, the termination criterion is also met and the optimized gradient switching sequence can be used for recording magnetic resonance image data in the further method step 43.

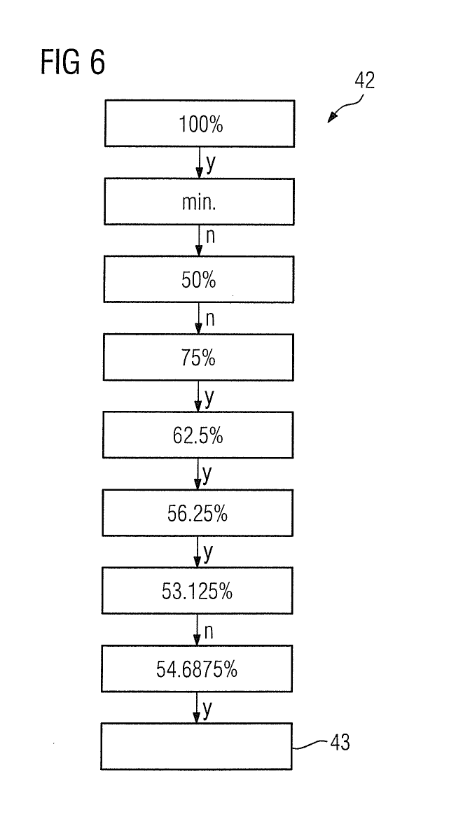

FIG. 6 illustrates an iterative adjustment of a slew rate of a gradient switching sequence according to a fifth embodiment of a method according to the invention.

As in FIGS. 4 and 5, here the step-wise adjustment of the slew rate in the further method step 42 is shown, depending on a starting value which is identified as 100 percent. It is assumed again here that the magnetic resonance sequence is still operable when the gradient switching sequence has at least 54 percent of the starting value.

In a first step, the slew rate is set to a minimum value, for example, one percent. At this value, the magnetic resonance sequence is not operable, so that the normal iterative adjustment of the slew rate is started.

In the case illustrated in FIG. 6, on a positive result for the operability test, the slew rate of the gradient switching sequence is reduced in the following iteration by a first step size and, on a negative result of the operability test, the slew rate of the gradient switching sequence is increased in the following iteration by a second step size, wherein the absolute value of a step size of the adjustment of the slew rate of the at least one gradient switching sequence is halved with each iteration. The termination criterion is set so that a step size of less than five percent exists and the magnetic resonance sequence is operable.

Thus, the slew rate of the gradient switching sequence is initially reduced in one 50 percent step to 50 percent. At 50 percent of the starting value, it is the case that the magnetic resonance sequence is no longer operable with the optimized gradient switching sequence. Thereafter, the slew rate of the gradient switching sequence is now increased in one 25 percent step to 75 percent. It is thus continued until the step size is 3.125 percent and the slew rate of the gradient switching sequence has been reduced to 53.125 percent. Although the termination criterion is met therein, the magnetic resonance sequence is not operable with the gradient switching sequence at this slew rate. Thus, the slew rate of the gradient switching sequence is increased again such that the gradient switching sequence has a slew rate of greater than 54 percent and is operable. Thus, the optimized gradient switching sequence can be used for recording magnetic resonance image data in the further method step 43.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for optimizing a magnetic resonance (MR) sequence for operating an MR apparatus, comprising:
providing an MR sequence to a computer, said MR sequence comprising a plurality of gradient switching sequences, each having a slew rate;
in said computer, optimizing at least one gradient switching sequence, among said plurality of gradient switching sequences, by an iterative adjustment of the slew rate of said at least one gradient switching sequence, thereby producing at least one optimized gradient switching sequence; and
from said computer, making said MR sequence, with said at least one optimized gradient switching sequence therein, available at an output of said computer in an electronic form for operating said MR apparatus.

2. A method as claimed in claim 1 comprising, in said computer, optimizing said at least one gradient switching sequence by executing an operability test of said MR sequence following each iteration of the iterative adjustment of said slew rate, with each successive iteration being executed dependent on a result of said operability test for an immediately preceding iteration.

3. A method as claimed in claim 2 comprising, in said computer, upon a positive result of said operability test, reducing said slew rate of said at least one gradient switching sequence in the successive iteration and, upon a negative result of said operability test, increasing said slew rate of said at least gradient switching sequence in said successive iteration.

4. A method as claimed in claim 3 comprising, in said computer, upon a positive result of said operability test, reducing said slew rate of said at least one gradient switching sequence in said successive iteration by a first step size and, upon a negative result of said operability test, increasing the slew rate of said at least one gradient switching sequence in said successive iteration by a second step size, with an absolute value of said second step size being smaller than an absolute value of said first step size.

5. A method as claimed in claim 3 comprising, in said computer, increasing or decreasing said slew rate in said successive iteration by a step size, with said step size being halved upon each iteration.

6. A method as claimed in claim 1 comprising, in said computer, for a first iteration of said iterative adjustment, setting said slew rate of said at least one gradient switching sequence to a minimum slew rate and executing an operability test of said MR sequence with said at least one gradient switching sequence at said minimum slew rate, and upon a positive result of said operability test, concluding optimization of said at least one gradient switching sequence, and generating said at least one optimized gradient switching sequence with said minimum slew rate.

7. A sequence optimizing device for optimizing a magnetic resonance (MR) sequence of an MR apparatus, said device comprising:
a processor;
said processor comprising an input interface that receives an MR sequence, said MR sequence comprising a plurality of gradient switching sequences, each having a slew rate;
said processor being configured to optimize at least one gradient switching sequence, among said plurality of gradient switching sequences, by an iterative adjustment of the slew rate of said at least one gradient switching sequence, thereby producing at least one optimized gradient switching sequence; and
said processor being configured to make said MR sequence, with said at least one optimized gradient switching sequence therein, available at an output of said processor in an electronic form for operating said MR apparatus.

8. A non-transitory, computer-readable data storage medium encoded with programming instructions, said storage medium being loaded into a control computer of a magnetic resonance (MR) apparatus, and said programming instructions causing said control computer to:
access an MR sequence, said MR sequence comprising a plurality of gradient switching sequences, each having a slew rate;
optimize at least one gradient switching sequence, among said plurality of gradient switching sequences, by an iterative adjustment of the slew rate of said at least one gradient switching sequence, thereby producing at least one optimized gradient switching sequence; and
make said MR sequence, with said at least one optimized gradient switching sequence therein, available at an output of said computer in an electronic form for operating said MR apparatus.
